(19) United States
(12) Patent Application Publication
(10) Pub. No.: US 2011/0037083 A1
(43) Pub. Date: Feb. 17, 2011

(54) LED PACKAGE WITH CONTRASTING FACE

(76) Inventors: ALEX CHI KEUNG CHAN, Sheung Shui (HK); DAVID EMERSON, Chapel Hill, NC (US); CHAK HAU PANG, Fanling (HK); JUN ZHANG, Huizhou City Guangdong (CN)

Correspondence Address: KOPPEL, PATRICK, HEYBL & DAWSON, 2815 Townsgate Road, SUITE 215, Westlake Village, CA, 91361-5827, US

(21) Appl. No.: 12/875,873

(22) Filed: Sep. 3, 2010

Related U.S. Application Data
(63) Continuation-in-part of application No. 12/321,059, filed on Jan. 14, 2009.

(51) Int. Cl. H01L 33/08; H01L 33/10

(52) U.S. Cl. 257/89; 257/98; 257/E33.068; 257/E33.056

(57) ABSTRACT

LED packages and LED displays utilizing the LED packages are disclosed, with the LED packages arranged to provide good contrast between the different pixels in an LED display while not reducing the perceived luminous flux or brightness of the display. One embodiment of an LED package comprises an LED chip and conversion material arranged to convert at least some light emitted from the LED chip. The package emits light from the conversion material or a combination of light from the conversion material and the LED chip. A reflective area is included around the LED chip that substantially reflects the package light and a contrasting area is included outside the reflective area and has a color that contrasts with the package light. LED displays according to the present invention comprise a plurality of LED packages arranged in relation to one another to produce messages or images, with the package providing improved pixel contrast.

This application is continuation-in-part of U.S. Patent Application Publication No. 2010/0155748, to Chan et al., filed on Jan. 14, 2009, and entitled “Aligned Multiple Emitter Package.”

### BACKGROUND OF THE INVENTION

1. Field of the Invention

This invention relates to light emitting diode packages and displays utilizing light emitting diode packages as their light source.

2. Description of the Related Art

Light emitting diodes (LED or LEDs) are solid state devices that convert electric energy to light, and generally comprise one or more active layers of semiconductor material sandwiched between oppositely doped layers. When a bias is applied across the doped layers, holes and electrons are injected into the active layer where they recombine to generate light. Light is emitted from the active layer and from all surfaces of the LED.

Technological advances over the last decade or more has resulted in LEDs having a smaller footprint, increased emitting efficiency, and reduced cost. LEDs also have an increased operation lifetime compared to other emitters. For example, the operational lifetime of an LED can be over 50,000 hours, while the operational lifetime of an incandescent bulb is approximately 2,000 hours. LEDs can also be more robust than other light sources and can consume less power. For these and other reasons, LEDs are becoming more popular and are now being used in more and more applications that have traditionally been the realm of incandescent, fluorescent, halogen and other emitters.

In order to use an LED chip in conventional applications it is known to enclose an LED chip in a package to provide environmental and/or mechanical protection, color selection, light focusing and the like. An LED package also includes electrical leads, contacts or traces for electrically connecting the LED package to an external circuit. In a typical two-pin LED package/component 10 illustrated in FIG. 1, a single LED chip 12 is mounted on a reflective cup 13 by means of a solder bond or conductive epoxy. One or more wire bonds 11 connect the ohmic contacts of the LED chip 12 to leads 15A and/or 15B, which may be attached to or integral with the reflective cup 13. The reflective cup 13 may be filled with an encapsulant material 16 and a wavelength conversion material, such as a phosphor, can be included in over the LED chip or in the encapsulant. Light emitted by the LED at a first wavelength may be absorbed by the phosphor, which may responsively emit light at a second wavelength. The entire assembly can then be encapsulated in a clear protective resin 14, which may be molded in the shape of a lens to direct or shape the light emitted from the LED chip 12.

A conventional LED package 20 illustrated in FIG. 2 may be more suited for high power operations which may generate more heat. In the LED package 20, one or more LED chips 22 are mounted onto a carrier such as a printed circuit board (PCB) carrier, substrate or submount 23. A metal reflector 24 mounted on the submount 23 surrounds the LED chip(s) 22 and reflects light emitted by the LED chips 22 away from the package 20. The reflector 24 also provides mechanical protection to the LED chips 22. One or more wirebond connections 21 are made between ohmic contacts on the LED chips 22 and electrical traces 25A, 25B on the submount 23. The mounted LED chips 22 are then covered with an encapsulant 26, which may provide environmental and mechanical protection to the chips while also acting as a lens. The metal reflector 24 is typically attached to the carrier by means of a solder or epoxy bond.

Different LEDs packages, such as those shown in FIGS. 1 and 2, can be used as the light source for signs and displays, both big and small. Large screen LED based displays (often referred to as giant screens) are becoming more common in many indoor and outdoor locations, such as at sporting arenas, race tracks, concerts and in large public areas such as Times Square in New York City. With current technology, some of these displays or screens can be as large as 60 feet tall and 60 feet wide. As technology advances it is expected that larger screens will be developed.

These screens can comprise thousands of “pixels” or “pixel modules”, each of which can contain one or a plurality of LED chips. The pixel modules can use high efficiency and high brightness LED chips that allow the displays to be visible from relatively far away, even in the daytime when subject to sunlight. In some signs each pixel can have a single LED chip, and pixel modules can have as few as three or four LEDs (one red, one green, and one blue) that allow the pixel to emit many different colors of light from combinations of red, green and/or blue light. In the largest jumbo screens, each pixel module can have dozens of LEDs. The pixel modules are arranged in a rectangular grid. In one type of display, the grid can be 640 modules wide and 480 modules high, with the size of the screen being dependent upon the actual size of the pixel modules.

One important aspect of conventional LED based displays is the contrast between pixels in the display, and for good image quality the contrast between pixels should be maximized. Often times, increasing contrast between pixels can result in reducing the overall emission intensity of the emitters in the pixels, and as a result, the overall emission intensity of the LED display.

LED packages have been developed to improve contrast in LED displays, with the packages having a surface area around the LED chips that comprises a color that contrasts with the light emitting from the LED chips. These packages, however, use only red, green and blue LEDs as their light source. It was generally thought that using this arrangement with LED packages emitting light that can comprise LED chip light and conversion material light (such as white light), would result in unacceptable losses in brightness of the emitted light. The concern was that the contrasting surface area around the LED chip would absorb the package light, thereby reducing the overall brightness of the package and signs or displays utilizing the packages.

### SUMMARY OF THE INVENTION

The present invention is directed to emitter packages, and more particularly to LED packages and LED displays utilizing the LED packages. The LED packages according to the present invention utilize LED chips and a conversion material that converts at least some of the light from the LED chips. The present invention is particularly applicable to LED packages that are capable of being mounted in a sign or display to produce a message or image. The LED packages provide good contrast between the different pixels in LED signs and displays, while not reducing the perceived luminous flux or brightness of the display.

One embodiment of an LED package according to the present invention comprises an LED chip and conversion material arranged to convert at least some light emitted from the LED chip. The package emits light from the conversion material or a combination of light from the conversion material and the LED chip. A reflective area is included around the LED chip that substantially reflects the package light and a contrasting area is included outside the reflective area and has a color that contrasts with the package light.

One embodiment of an LED display according to the present invention comprises a plurality of LED packages mounted in relation to one another to generate an message or image. At least some of the LED packages comprise an LED chip and conversion material arranged in a reflective cup, with the conversion material converting at least some light emitted from the LED chip. The LED packages emit package light from the conversion material or a combination of light from the conversion material and the LED chip. The reflective area substantially reflects the package light, with the package further comprising a contrasting area that is outside the reflective area and has a color that contrasts with the package light.

Another embodiment of an LED package according to the present invention comprises an LED chip and a conversion material arranged to absorb light from the LED chip and re-emit light at a different wavelength. The package emits a package light comprising the re-emitted light or a combination of light from the LED chip and the re-emitted light. The LED chip is mounted within a reflective cup having an upper surface with a color that contrasts with the light emitted from the LED chip.

Another embodiment of an LED package according to the present invention comprises a plurality LED chips electrically coupled in a single circuit. Surfaces directly around the LED chips comprise a reflective area that substantially reflects light emitted from the LED chips. A contrasting area is included that is outside the reflective area and has a color that contrasts with the light emitted from the LED chips.

These and other aspects and advantages of the invention will become apparent from the following detailed description and the accompanying drawings which illustrate by way of example the features of the invention.

### BRIEF DESCRIPTION OF THE DRAWINGS

FIG. 1 is a side view of a conventional light emitting diode package;

FIG. 2 is a perspective view of another conventional light emitting diode package;

FIG. 3 is a perspective view of one embodiment of an LED package according to the present invention;

FIG. 4 is a top view of the LED package shown in FIG. 3;

FIG. 5 is a sectional view of the LED package shown in FIG. 4, taken along section lines 5-5;

FIG. 6 is a side view of one embodiment of an LED display according to the present invention;

FIG. 7 is a perspective view of another LED package according to the present invention;

FIG. 8 is top view of the LED package shown in FIG. 7; and

FIG. 9 is a schematic showing interconnections between LED chips in one embodiment of an LED package according to the present invention.

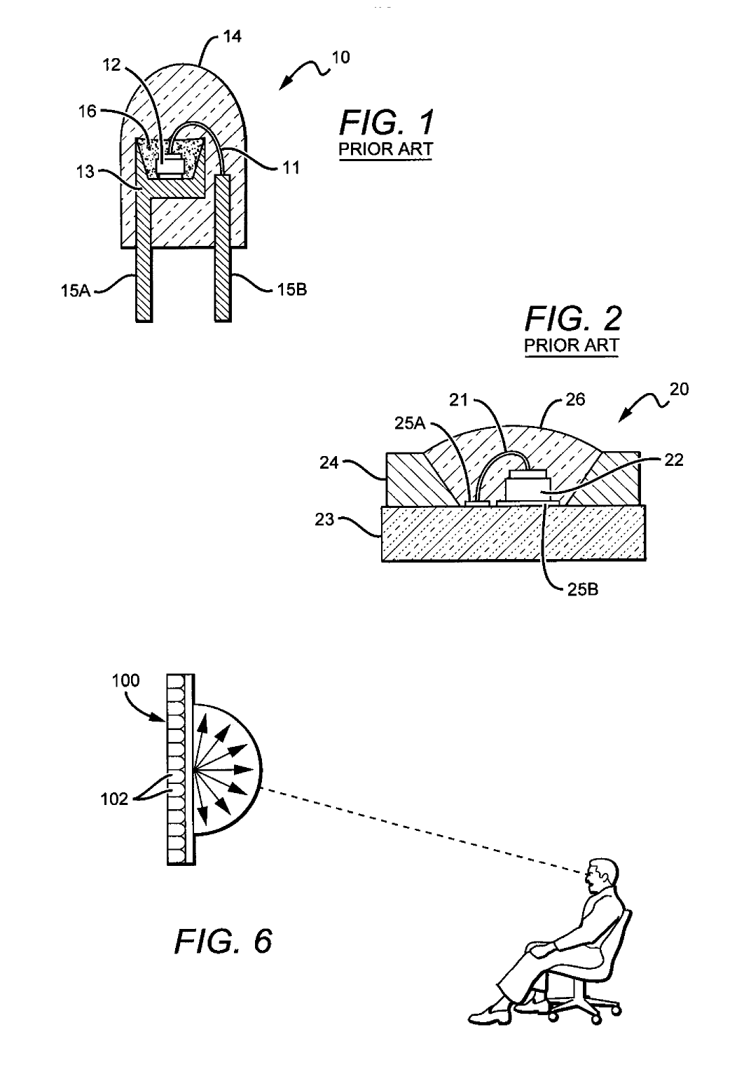

### DETAILED DESCRIPTION OF THE INVENTION

The present invention is directed to LED packages and LED displays utilizing LED packages, wherein the LED packages comprise different arrangements to increase emission contrast between adjacent ones of the LED packages in the display. The packages can comprise one or more LED chips and a conversion material, with the LED chips mounted to a submount or within a package casing. Portions of the outer surface of the submount or casing can comprise a color that contrasts with the color of light emitting from the LED package.

In some embodiments, areas of the submount or casing directly surrounding the LED chips can comprise a material that is substantially the same color as, or is reflective of, the LED chip light. This reflective area can at least partially comprise a reflective cup. The area of the submount outside of this reflective area can comprise a material that contrasts with the LED chip light. In embodiments having white emitting LED chips, the area directly around the LED chips can comprise a material that is reflective of white light, while the area around the white reflective material can contrast with white light. In some of these embodiments, the white reflective material can be white colored, and the contrasting area can be black colored. It is understood that the contrasting area can also be many other colors, including but not limited to blue, brown, grey, red, green, etc.

This combination of reflective and contrasting materials provides for improved contrast between the light emitting from the LED chips and the surrounding package. This contrast helps provide for contrast between the LED packages used in an LED display, thereby providing contrast between the different pixels in the display. This improved contrast can result in a higher quality picture for the viewer. At the same time, the LED packages utilizing white emitting LED chips provide the unexpected result of not absorbing an unreasonable amount of LED package light. It was previously believed that using this type of arrangement with white or other wavelength converted light could result in unreasonable losses of package light. Although some light from the LED chips may be absorbed by the contrasting material, when they used in a display the contrast can result in the viewer unexpectedly perceiving essentially the same amount of light compared to displays having LED packages without the contrasting material. The contrast compensates for any absorbed light such that the viewer perceives substantially the same image brightness from the display.

The embodiments below are described with reference to LED packages emitting at least some LED light that has been wavelength converted. This generally relates to LED chips arranged with a conversion material, such as by example a phosphor, where at least some LED light passes through a conversion material so that some of the LED light is absorbed by the conversion material and re-emitted at a different wavelength of light. In some of these embodiments the LED packages can emit a light that is a combination of light from the LED and the conversion material. The wavelength converted light can comprise different colors of light including different color temperatures of white light and blue shifted yellow (BSY) light. BSY light generally relates to blue emitting LEDs covered by a yellow/green conversion material wherein at least some of the blue LED light is converted by the conversion material. The resulting LED chip emits a combination of blue from the LED and yellow/green from the conversion material.

The packages according to the present invention can also comprise a plurality of LED chips, each of which generates a white wavelength converted light. In other embodiments, the LED packages can utilize a plurality of chips that emit different colors of light that are arranged to combine to produce a white light. Techniques for generating white light from a plurality of discrete light sources to provide improved CRI at the desired color temperature have been developed that utilize different hues from different discrete light sources. Such techniques are described in U.S. Pat. No. 7,213,940, entitled “Lighting Device and Lighting Method”. In one such arrangement a 452 nm peak blue InGaN LEDs were coated with a yellow conversion material, such as a YAG:Ce phosphor, to provide a color that was distinctly yellow and has a color point that fell well above the black body locus on the CIE diagram. Blue emitting LEDs coated by yellow conversion materials are often referred to as blue shifted yellow (BSY) LEDs or LED chips. The BSY emission is combined with the light from reddish AlInGaP LEDs that “pulls” the yellow color of the yellow LEDs to the black body curve to produce warm white light.

In multiple LED chips embodiments, the LED chips can be coupled in the package so that electrical signals can be applied to each of the LED chips be on or off, or causing them to emit light at the desired intensity. In still other embodiments, the LED chips can be coupled together such that a single electrical signal controls whether the LED chips are on or off. These embodiments can comprise LED chips coupled together in series.

The LED packages according to the present invention can be used in LED signs and displays, but it is understood that they can be used in many different applications. The LED packages can comply with different industry standards making them appropriate for use in LED based signs, channel letter lighting, or general backlighting and illumination applications. Some embodiments can also comprise a flat top emitting surface making them compatible to mate with light pipes. These are only a few of the many different applications for the LED packages according to the present invention.

Some LED package embodiments according to the present invention can comprise a single LED chip or multiple LED chips mounted to a submount or casing. These packages can also comprise a reflective cup surrounding the LED chip or chips. The upper surface of the reflective cup surrounding the LED chips can comprise a material that contrasts with that of the light emitted by the LED chips. The portion of the submount exposed within the cup, and/or the reflective surfaces within the cup can also comprise a material that is reflective of the light from the LED chips. In some of these embodiments light emitted from the LED chips can be white or other wavelength converted light, and the surface of the submount within the reflective cup and the reflective surfaces of the cup can be white or otherwise reflective of the white or wavelength converted light. The contrasting upper surface of the reflective cup can be many different colors, but in some embodiments is black.

The present invention is described herein with reference to certain embodiments, but it is understood that the invention can be embodied in many different forms and should not be construed as limited to the embodiments set forth herein. In particular, many different LED chips, reflective cup and lead frame arrangements can be provided beyond those described above, and the encapsulant can provide further features to improve the reliability and emission characteristics from the LED packages and LED displays utilizing the LED packages. Although the different embodiments of LED packages are discussed herein as being used in an LED display, the LED packages can be used in many different lighting applications.

It is also understood that when an element such as a layer, region or substrate is referred to as being “on” another element, it can be directly on the other element or intervening elements may also be present. Furthermore, relative terms such as “above” and “below”, and similar terms, may be used herein to describe a relationship of one layer or another region. It is understood that these terms are intended to encompass different orientations of the device in addition to the orientation depicted in the figures.

Although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-sectional view illustrations that are schematic illustrations of embodiments of the invention. As such, the actual thickness of the layers can be different, and variations from the shapes of the illustrations as a result, for example, of manufacturing techniques and/or tolerances are expected. Embodiments of the invention should not be construed as limited to the particular shapes of the regions illustrated herein but are to include deviations in shapes that result, for example, from manufacturing. A region illustrated or described as square or rectangular will typically have rounded or curved features due to normal manufacturing tolerances. Thus, the regions illustrated in the figures are schematic in nature and their shapes are not intended to illustrate the precise shape of a region of a device and are not intended to limit the scope of the invention.

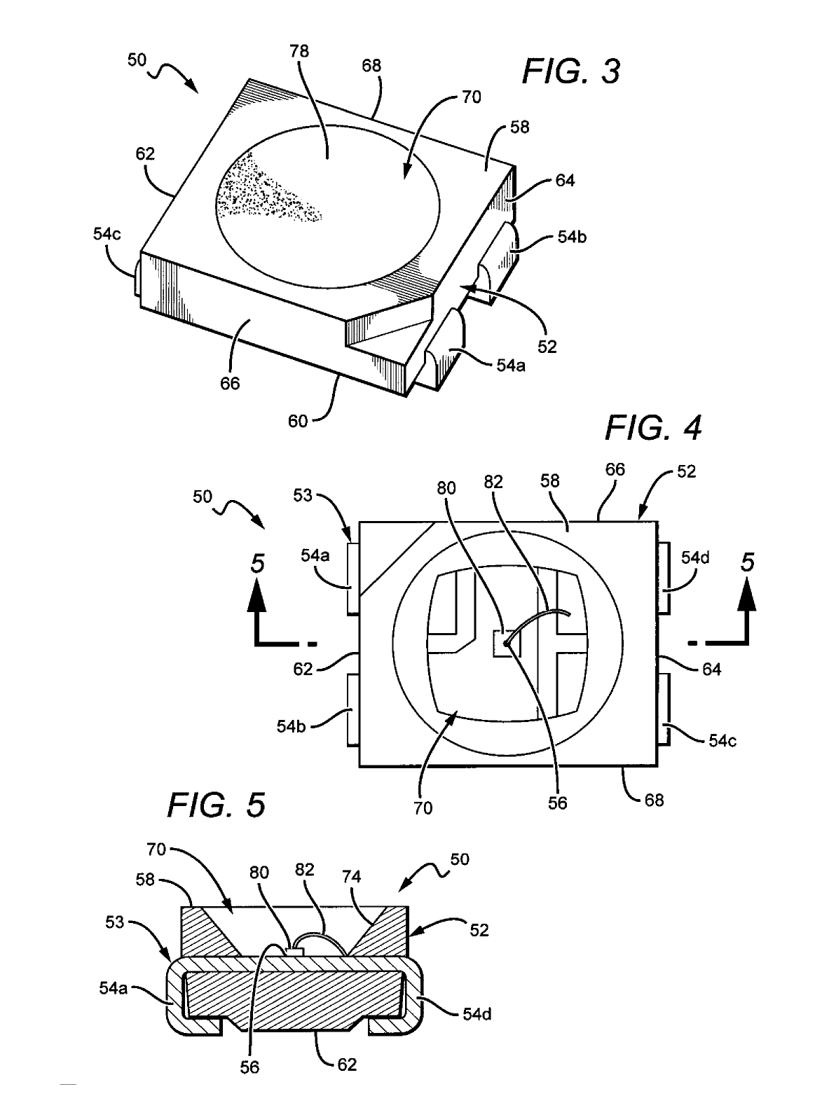

FIGS. 3-5 show one embodiment of an emitter package according to the present invention that comprises a surface mount device (SMD). That is, the device is arranged so that is can be mounted to a structure, such as a printed circuit board (PCB), using surface mount technology. It is understood that the present invention is also applicable to other emitter package types beyond SMDs, such as pin-mounting emitter packages. The package 50 comprises a casing (or submount) 52 that carries an integral lead frame 53. The lead frame 53 comprising a plurality of electrically conductive connection parts used to conduct an electrical signal to the package's light emitters, and to also assist in dissipating heat generated by the emitters.

The lead frame 53 can be arranged in many different ways and different numbers of parts can be utilized in different package embodiments. The package 50 is described below as utilizing one emitter, and in the embodiment shown the lead frame 53 is arranged to apply an electrical signal to the emitter. The lead frame 54 comprises conductive parts 54a-d, with two of the conductive parts used for applying an electrical signal to the emitter. In the embodiment shown, anode for applying electrical signals to the emitter can be the second conductive part 54b and the cathode can be the fourth conductive part 54d, but it is understood that other embodiments can utilize others of the conductive parts 54a-d. The remaining conductive parts 54a and 54c can be included to provide mounting stability and to provide an additional thermal path for dissipating heat from the emitter. In the embodiment shown, the second conductive part 54b has a die attach pad 56 for mounting an emitter such as a light emitting diode (LED).

The casing 52 can have many different shapes and sizes and in the embodiment shown is generally square or rectangular, with upper and lower surfaces 58 and 60, first and second side surfaces 62 and 64 and first and second end surfaces 66 and 68. The upper portion of the casing further comprises a recess or cavity 70 extending from the upper surface 58 into the body of the casing 52 to the lead frame 53. The package emitter is arranged on the lead frame 53 such that light from the emitters emits from the package 50 through the cavity 70. The cavity 70 forms a reflective cup around the emitter to help reflect emitter light out of the package 50. In some embodiments, a reflective insert or ring (not shown) may be positioned and secured along at least a portion of a side or wall 74 of the cavity 70. The effectiveness of the reflectivity of the ring and the emission angle of the package can be enhanced by tapering the cavity 70 and the ring is carried therein inwardly toward the interior of the casing. By way of example a reflector angle of about 50 degrees provides for a suitable reflectivity and viewing angle.

In some embodiments, the cavity 70 may be at least partially filled with a fill material (or encapsulant) 78 that can protect and positionally stabilize the lead frame 53 and the emitter carried thereby. In some instances, the fill material 78 may cover the emitters and the portions of the lead frame 53 exposed through the cavity 70. The fill material 78 may be selected to have predetermined optical properties so as to enhance the projection of light from the LEDs, and in some embodiments is substantially transparent to the light emitted by the package's emitters. The fill material 78 can also be flat so that it is approximately the same level as the upper surface 58, or it can be shaped in a lens, such as hemispheric or bullet shape. Alternatively, the fill material can be fully or partially concave in the cavity 760. The fill material 78 may be formed from a resin, an epoxy, a thermoplastic polycondensate, glass, and/or other suitable materials or combinations of materials. In some embodiments, materials may be added to the fill material 78 to enhance the emission, absorption and/or dispersion of light to and/or from the LEDs.

The casing 52 may be fabricated of material that is preferably both electrically insulating and thermally conductive. Such materials are well-known in the art and may include, without limitation, certain ceramics, resins, epoxies, thermoplastic. polycondensates (e.g., a polyphthalamide (PPA)), and glass. The package 50 and its casing 52 may be formed and/or assembled through any one of a variety of known methods as is known in the art. For example, the casing 52 may be formed or molded around conductive parts 54a-d, such as by injection molding. Alternatively, the casing may be formed in sections, for example, top and bottom sections with conductive parts formed on the bottom section. The top and bottom sections can then be bonded together using known methods and materials, such as by an epoxy, adhesive or other suitable joinder material.

Packages according to the present invention can use many different emitters, with the package 50 utilizing an LED chip 80. Different embodiments can have different LED chips that emit different colors of light, and in the embodiment shown, the package 50 comprises an LED chip emits white or other wavelength converted light.

LED chip structures, features, and their fabrication and operation are generally known in the art and only briefly discussed herein. LED chips can have many different semiconductor layers arranged in different ways and can emit different colors. The layers of the LED chips can be fabricated using known processes, with a suitable process being fabrication using metal organic chemical vapor deposition (MOCVD). The layers of the LED chips generally comprise an active layer/region sandwiched between first and second oppositely doped epitaxial layers, all of which are formed successively on a growth substrate or wafer. LED chips formed on a wafer can be singulated and used in different applications, such as mounting in a package. It is understood that the growth substrate/wafer can remain as part of the final singulated LED chip or the growth substrate can be fully or partially removed.

It is also understood that additional layers and elements can also be included in the LED chips, including but not limited to buffer, nucleation, contact and current spreading layers as well as light extraction layers and elements. The active region can comprise single quantum well (SQW), multiple quantum well (MQW), double heterostructure or super lattice structures.

The active region and doped layers may be fabricated from different material systems, with one such system being Group-III nitride based material systems. Group-III nitrides refer to those semiconductor compounds formed between nitrogen and the elements in the Group III of the periodic table, usually aluminum (Al), gallium (Ga), and indium (In). The term also refers to ternary and quaternary compounds such as aluminum gallium nitride (AlGaN) and aluminum indium gallium nitride (AlInGaN). In a preferred embodiment, the doped layers are gallium nitride (GaN) and the active region is InGaN. In alternative embodiments the doped layers may be AlGaN, aluminum gallium arsenide (AlGaAs) or aluminum gallium indium arsenide phosphide (AlGaInAsP) or aluminum indium gallium phosphide (AlInGaP) or zinc oxide (ZnO).

The growth substrate/wafer can be made of many materials such as silicon, glass, sapphire, silicon carbide, aluminum nitride (AlN), gallium nitride (GaN), with a suitable substrate being a 4H polytype of silicon carbide, although other silicon carbide polytypes can also be used including 3C, 6H and 15R polytypes. Silicon carbide has certain advantages, such as a closer crystal lattice match to Group III nitrides than sapphire and results in Group III nitride films of higher quality. Silicon carbide also has a very high thermal conductivity so that the total output power of Group-III nitride devices on silicon carbide is not limited by the thermal dissipation of the substrate (as may be the case with some devices formed on sapphire). SiC substrates are available from Cree Research, Inc., of Durham, N.C. and methods for producing them are set forth in the scientific literature as well as in a U.S. Pat. Nos. Re. 34,861; 4,946,547; and 5,200,022. LEDs can also comprise additional features such as conductive current spreading structures and current spreading layers all of which can be made of known materials deposited using known methods.

The LED chip 80 may be electrically coupled to the attach pad 56 on the second conductive part 54b by means of an electrically and thermally conductive bonding material such as a solder, adhesive, coating, film, encapsulant, paste, grease and/or other suitable material. In a preferred embodiment, the LEDs may be electrically coupled and secured to their respective pads using a solder pad on the bottom of the LEDs such that the solder is not visible from the top. A wire bond 82 can be included running between the LED chip 80 and the fourth conductive part 54d. An electrical signal applied across the second and fourth conductive parts causes the LED chip 80 to emit light.

The fabrication of the conductive parts 54a-d may be accomplished by stamping, injection molding, cutting, etching, bending or through other known methods and/or combinations of methods to achieve the desired configurations. For example, the conductive parts 54a-d can be partially metal stamped (e.g., stamped simultaneously from a single sheet of relevant material), appropriately bent, and fully separated or fully separated following the formation of some or all of the casing.

The conductive parts 54a-d may be made from an electrically conductive metal or metal alloy, such as copper, a copper alloy, and/or other suitable low resistivity, corrosion resistant materials or combinations of materials. As noted, the thermal conductivity of the leads may assist, to some extent, in conducting heat away from the LED chip 80.

Some or all of the LED chips described herein can be coated with a conversion material, such as one or more phosphors with the phosphors absorbing at least some of the LED chip light and emitting a different wavelength of light such that the LED chip emits a combination of light from the LED chip and the phosphor (i.e. wavelength converted light). In other embodiments, the conversion material can be located in other areas of the package, including but not limited to the encapsulant or surfaces of the package (e.g. reflective cup).

In one embodiment according to the present invention white emitting LED chips can comprise an LED chip that emits light in the blue wavelength spectrum and the phosphor absorbs some of the blue light and re-emits yellow. The LED chips emit a white light combination of blue and yellow light. In other embodiments, the LED chips emit a non-white light combination of blue and yellow light as described in U.S. Pat. No. 7,213,940 mentioned above. In some embodiments the phosphor comprises commercially available YAG:Ce, although a full range of broad yellow spectral emission is possible using conversion particles made of phosphors based on the (Gd, Y)₃(Al, Ga)_{5O12}:Ce system, such as the _{y3}A_{15O12}:Ce (YAG). Other yellow phosphors that can be used for white emitting LED chips include:

### Tb₃₋ₓREₓO₁₂:Ce(TAG); RE=Y, Gd, La, Lu; or

### Sr_{2-x-y}BaₓCa_{y}SiO₄:Eu.

Alternatively, in other embodiments the LED chips emit other colors of light by being coated with the desired conversion material (e.g. phosphor) that provides the desired emission. For example, red emitting LED chips can comprise LED chips covered by a phosphor that absorbs the LED chip light and emits a red light. The LED chips can emit blue or UV light and some phosphors appropriate for these structures can comprise: Lu₂O₃:Eu³⁺; (Sr₂₋ₓLaₓ) (Ceₗ₋ₓEuₓ)O₄; Sr₂₋ₓEuₓCeO₄; SrTiO₃:Pr³⁺, Ga³⁺; CaAlSiN₃: Eu²⁺; and Sr₂Si₅N₈: Eu²⁺.

LED chips can be coated with a phosphor using many different methods, with one suitable method being described in U.S. patent application Ser. Nos. 11/656,759 and 11/899,790, both entitled “Wafer Level Phosphor Coating Method and Devices Fabricated Utilizing Method”, and both of which are incorporated herein by reference. Alternatively the LEDs can be coated using other methods such as electrophoretic deposition (EPD), with a suitable EPD method described in U.S. patent application Ser. No. 11/473,089 entitled “Close Loop Electrophoretic Deposition of Semiconductor Devices”, which is also incorporated herein by reference. Furthermore, LEDs may have vertical or lateral geometry as is known in the art. Those comprising a vertical geometry may have a first contact on a substrate and a second contact on a p-type layer. An electrical signal applied to the first contact spreads into the n-type layer and a signal applied to the second contact spreads into a p-type layer. In the case of Group-III nitride devices, it is well known that a thin semitransparent typically covers some or the entire p-type layer. It is understood that the second contact can include such a layer, which is typically a metal such as platinum (Pt) or a transparent conductive oxide such as indium tin oxide (ITO).

LEDs may also comprise a lateral geometry, wherein both contacts are on the top of the LEDs. A portion of the p-type layer and active region is removed, such as by etching, to expose a contact mesa on the n-type layer. A second lateral n-type contact is provided on the mesa of the n-type layer. The contacts can comprise known materials deposited using known deposition techniques.

In the embodiment shown, the package 50 is arranged such that the upper surface 58 has a color that contrasts with that of the light emitted from the package 50 through the recess/cavity 70. In most embodiments, light emitted from the cavity 70 can comprise light emitted by the LED chip 80, but in other embodiments the light emitted through the cavity 70 can also comprise light converted by conversion materials located in different places in the package. This can include conversion material over the LED chip 80, mixed in the fill material 78 or on surfaces exposed in the recess 70.

In the embodiment shown, the LED package 50 emits white light from the recess 70, and the upper surface can comprise a color that contrasts with white. Many different colors can be used such as blue, brown, grey, red, green, purple, etc., with the embodiment shown having a black color on its upper surface 58. The black coloring can be applied using many different known methods. It can be applied during molding of the casing 52, or can be applied at a later step in the package fabrication process using different methods such as screen printing, ink jet printing, painting, etc.

To further contrast the recess or cavity from the contrasting color of the upper surface 58, surfaces within the recess can also have a color or be coated with a material that substantially reflects light emitting from the LED and/or the surrounding conversion material. In some embodiments that surface side wall 74 and the other surfaces of the casing visible through the recess, can comprise a material that substantially reflects the light from the LED chip 80. The surfaces of the conductive parts 54a-d exposed through the recess 70 and spaces between the conductive parts 54a-d may all be further coated with a reflective layer (not shown) to improve reflection of light emitted by the LED chip 80 by reflecting light from the LED chip 80 that would have otherwise been absorbed by these package components. The reflective layer preferably comprises Ag, but it is understood that other reflective materials such as Al may be provided at a variety of thicknesses. The reflective layer can completely or partially cover portions of the conductive parts not occupied by LED chip 80 or wire bond 82, but it is understood that as general matter, the more area covered by reflective layer a larger reflective area is obtained, which can improve the overall package reflectivity.

The cavity 70 can take many different shapes such as circular as shown, or oval, square rectangular or other polygon shapes. The contrasting area of the upper surface 58 can take many different shapes and can cover all or less than all of the upper surface. In one embodiment, upper surface 58 can be covered by the contrasting material, with its shape defined by the shape of the upper surface 58.

As discussed above, the darker contrasting color of the upper surface 58 can result in absorption of some light as it emits from the LED chip 80 and out the package recess 70. To help minimize the amount of LED light that is absorbed, the upper surface 58 can be arranged such that it is above the LED chip, so that little or no LED light emits directly on the upper surface. That is, the LED chip 80 is arranged at the base of the cavity 70, and the upper surface 58 is at the top of the reflective cup, which is above the LED chip 80. As a result, light from the LED chip 80 emits out of the cavity 70 without emitting directly on the upper surface 58. This combination of contrasting materials provides the contrast advantages mentioned above, with the unexpected result of little or no perceived reduction in LED package (or LED display brightness) as a result of emitter light being absorbed by the darker surfaces.

As mentioned above, the LED package embodiments according to the present invention can be used for many different applications, but are particularly applicable for use in LED displays to provide tilted peak emission patterns. FIG. 6 shows one embodiment of an LED display 100 according to the present invention that can utilize a plurality of LED packages 102 according to the present invention to improve pixel contrast, and different LED display embodiments can have all or some LED packages with the improved contrast. Different LED displays according to the present invention can have more than 300,000 pixels, while other embodiments can have 200,000 to 300,000 pixels. Still other embodiments can have between 100,000 and 200,000 pixels.

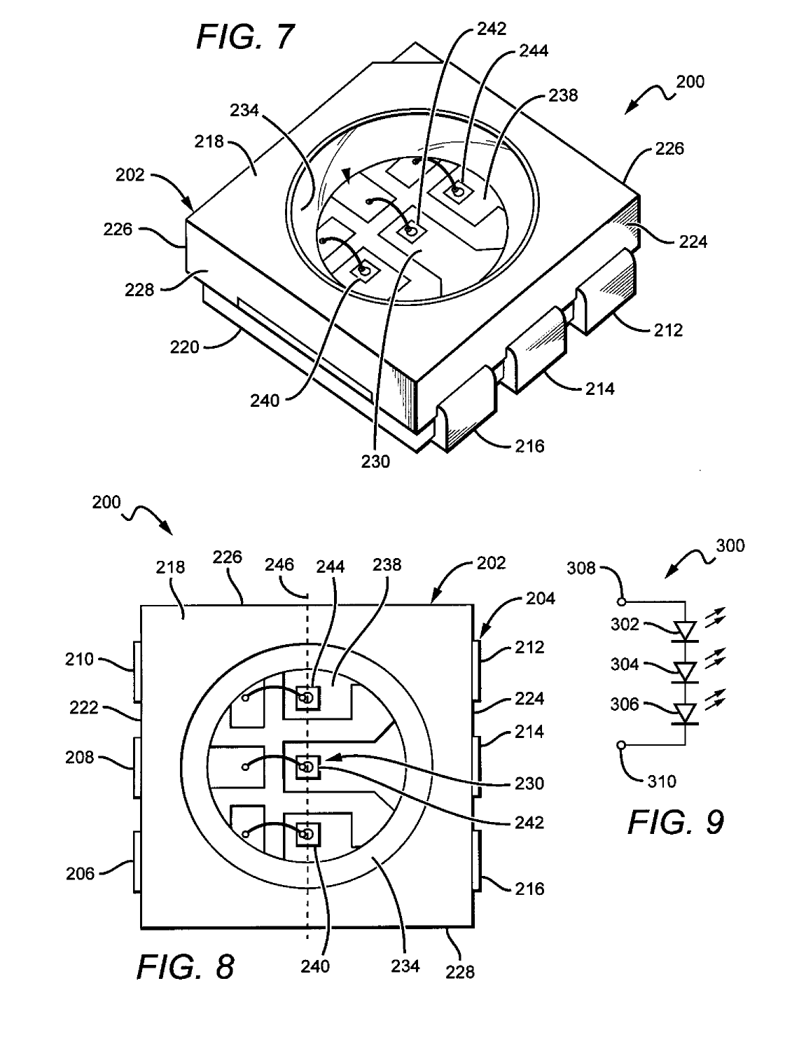

It is understood that different embodiments of LED packages according to the present invention can be arranged in many different ways and can have many different components. The different embodiments can have multiple emitters or LED chips, with FIGS. 7 and 8 showing another embodiment of LED package 200 according to the present invention also arranged as a SMD, but having three LED chips. Like the embodiment above, the package 200 comprises a casing 202 that carries an integral lead frame 204. The lead frame 204 comprising a plurality of electrically conductive connection parts used to conduct an electrical signals to the package's light emitters, and to also assist in dissipating heat generated by the emitters.

The lead frame is arranged so that each of the emitters is driven by a respective electrical signal. Accordingly, there are six conductive parts in the embodiment shown that comprise a pair of conductive parts for each emitter with an electrical signal applied to each of the emitters through its conductive part pair. For the package 200, the conductive parts comprise first, second and third anode parts 206, 208, 210, and first, second and third cathode parts 212, 214, 216 each having an emitter attach pad. The conductive parts and attach pads can be made of the same material as those described above.

Like above, the casing 202 is generally square or rectangular, with upper and lower surfaces 218 and 220, first and second side surfaces 222 and 224 and first and second end surfaces 226 and 228. The upper portion of the casing further comprises a recess or cavity 230 extending from the upper surface 218 into the body of the casing 202 to the lead frame 204. Emitters are arranged on the lead frame 204 such that light from the emitters emits from the package 200 through the cavity 230. In some embodiments, a reflective insert or ring (not shown) may be positioned and secured along at least a portion of a side or wall 234 of the cavity 230.

As with package 50, in some embodiments, the cavity 230 may be at least partially filled with a fill material (or encapsulant) 238 that can protect and positionally stabilize the lead frame 204 and the emitters carried thereby. The fill material 238 and casing 202 can be from the same methods and materials mentioned above for package 50.

In the illustrative embodiment depicted, the package 200 utilizes first, second and third LED chips 240, 242, 244 each of which can emit the same color of light or different color of light than the others. In the embodiment shown, the LED chips 240, 242, 244 can emit blue, green and red colors, respectively, so that when appropriately energized the LEDs produce in combination a substantially full range of colors. Further, when appropriately energized, the LEDs 240, 242, 244 emit a white light combination of different color temperatures.

The cathode parts 212, 214, 216 comprise central surfaces or mounting pads for carrying the LED chips 240, 242, 244 in a linear array that extends in a direction 246 perpendicular to the side surfaces 222 and 224, with the LEDs 240, 242, 244 being aligned generally along a central axis of the casing 202. This alignment can provide for improved color uniformity at different viewing angles compared to packages having LEDs arranged in other ways, such as in a cluster.

In the embodiment shown, the package 200 is also arranged such that the upper surface 218 has a color that contrasts with that of the light emitted from the package 200 through the cavity 230. As discussed above, this can include light from LED chips 240, 242, 244 and/or light from one or more conversion materials arranged within the recess. In the embodiment shown, the LED package 200 can comprise emitting LED chips 240, 242, 244 or can emit a white light combination of light from it LED chips 240, 242, 244. The upper surface 218 can comprise a color that contrasts with white. Many different colors can be used such as blue, brown, grey, red, green, purple, etc., with the embodiment shown having a black color on its upper surface 218. The black coloring can be applied using one of the methods described above.

To further contrast the recess or cavity from the contrasting color of the upper surface 218, surfaces within the recess 230 can also have a color, or be coated with a material, that reflects light emitting from the LEDs and/or the surrounding conversion material, as discussed above. Furthermore, other surfaces exposed through the recess 230 can also and spaces between the conductive parts may all be coated with a reflective layer (not shown) as discussed above. The darker contrasting color of the upper surface 218 can result in absorption of some light as it emits from the LED chips 240, 242, 244 and out the package recess 230. Like above, to help minimize the amount of LED light that is absorbed, the upper surface 218 can be arranged such that it is above the LED chip, so that little or no LED light shines directly on the upper surface. This arrangement provides for the advantages discussed above, including improved pixels contrast while not substantially reducing the perceived luminous flux or brightness of an LED display utilizing the packages.

The embodiment above is described with reference to first, second and third anode and cathode parts that allow for respective electrical signals to be applied to the each of the LED chips, it is understood that the multiple the LED chips can be coupled together in many other ways. The LED chips can be coupled together in many different serial and parallel interconnect combinations. In some embodiments, the LED chips can be coupled together in a single circuit between a single anode and a single cathode used to apply an electrical signal to the LED chips.

Interconnect circuit 300 shown in FIG. 9 shows one embodiment of a single circuit arrangement according to the present invention. Multiple LED chips 302, 304, 306 can be interconnected in series between a single anode 308 and single cathode 310, such that a single electrical signal applied to the first of the LED chips 302 causes all the LED chips 302, 304, 306 to emit light. This allows a single electrical signal to control all the LED chips to an on or off state. It is understood that in other embodiments the LED chips can be connected in parallel between the single anode and single cathode, or other serial/parallel combinations.

It is understood that different embodiments of the emitter packages can be arranged in many different ways beyond the embodiments mentioned above. The packages can have many different surface mount or other types of mounting arrangements and can comprise reflective cups having different shapes and sizes. Still other embodiments can be arranged without a reflective cup, with one of these embodiments comprising LED chip or chips mounted to a submount. The light reflective and contrasting materials can be on the submount around the LEDs, and in some embodiments an encapsulant in the form of a lens can be molded over the LED chips.

Although the present invention has been described in detail with reference to certain preferred configurations thereof, other versions are possible. Therefore, the spirit and scope of the invention should not be limited to the versions described above.

We claim:

1. A light emitting diode (LED) package, comprising:
an LED chip and conversion material arranged to convert at least some light emitted from said LED chip, said package emitting light from said conversion material or a combination of light from said conversion material and said LED chip;
a reflective area around said LED chip that substantially reflects said package light; and
a contrasting area outside said reflective area having a color that contrasts with said package light.

2. The LED package of claim 1, wherein said package light comprises a blue shifted yellow (BSY) light.

3. The LED package of claim 1, wherein said package light comprises a white light.

4. The LED package of claim 1, further comprising a casing with a lead frame, said LED chip electrically coupled to said lead frame

5. The LED package of claim 1, further comprising a casing, wherein said reflective area comprises a cavity in said casing, said LED chip mounted within said cavity.

6. The LED package of claim 5, wherein said cavity forms a reflective cup around said LED chip.

7. The LED package of claim 1, comprising a surface mount device (SMD).

8. The LED package of claim 1, wherein said reflective area comprises a reflective cup.

9. The LED package of claim 1, wherein said contrasting area is black.

10. The LED package of claim 1, wherein said contrasting area is around said reflective area.

11. The LED package of claim 1, wherein said contrasting area is at a level above said LED chip.

12. The LED package of claim 11, wherein said contrasting area and said LED chip are arranged so that said LED light emits from said package without emitting directly on said contrasting area.

13. A light emitting diode (LED) display, comprising:
a plurality of LED packages mounted in relation to one another to generate a message or image, at least some of said LED packages comprising an LED chip and conversion material arranged in a reflective cup with said conversion material converting at least some light emitted from said LED chip, said at least some packages emitting package light from said conversion material or a combination of light from said conversion material and said LED chip, said reflective area substantially reflecting said package light, said package further comprising a contrasting area that is outside said reflective area and having a color that contrasts with said package light.

14. The LED display of claim 13, wherein said LED display comprises higher pixel contrast compared to the same LED display having LED packages without a contrasting area.

15. The LED display of claim 13, wherein said reflective area of each of said at least some LED packages comprises a reflective cup around said LED chip.

16. The LED display of claim 13, wherein each of said at least some LED packages comprises a surface mount device (SMD).

17. The LED display of claim 13, wherein each of said at least some LED packages emits white light.

18. The LED display of claim 13, wherein each of said at least some LED packages emits blue shifted yellow (BSY) light.

19. The LED display of claim 13, wherein said contrasting area in each of said at least some LED packages is black.

20. The LED display of claim 13, wherein said contrasting area in each of said at least some LED packages is around said reflective area.

21. The LED display of claim 13, wherein said contrasting area in each of said at least some LED packages is at a level above said LED chip.

22. The LED display of claim 13, wherein said contrasting area is arranged in each of said at least some LED packages so that LED light emits from said package without emitting directly on said contrasting area.

23. A light emitting diode (LED) package, comprising:
an LED chip and a conversion material arranged to absorb light from said LED chip and re-emit light at a different wavelength, said package emitting a package light comprising said re-emitted light or a combination of light from said LED chip and said re-emitted light, said LED chip mounted within a reflective cup having upper surface with a color that contrasts with the light emitted from said LED chip.

24. The LED package of claim 23, wherein surfaces of said reflective cup are substantially reflective of said package light.

25. The LED package of claim 23, wherein surfaces of said reflective cup are white.

26. The LED package of claim 23, wherein said upper surface is black.

27. The LED package of claim 23, comprising a surface mount device (SMD).

28. The LED package of claim 23, wherein said upper surface and said LED chip are arranged so that LED light emits from said package without emitting directly on said upper surface.

29. A light emitting diode (LED) package, comprising:
a plurality of LED chips electrically coupled in a single circuit, wherein surfaces directly around said LED chips comprise a reflective area that substantially reflects light emitted from said LED chips, and a contrasting area that is outside said reflective area having a color that contrasts with the light emitted from said LED chips.

30. The LED package of claim 29, wherein said single circuit comprises a single anode and single cathode for applying an electrical signal to said LED chips.

31. The LED package of claim 29, wherein at least some of said LED chips emit white light.

32. The LED package of claim 29, wherein at least some of said LED chips emit blue shifted yellow (BSY) light.

33. The LED package of claim 29, further comprising a casing, wherein said reflective area comprises a cavity in said casing, said LED chips mounted within said cavity.

34. The LED package of claim 33, wherein said cavity forms a reflective cup around said LED chip.

35. The LED package of claim 29, comprising a surface mount device (SMD).

36. The LED package of claim 29, wherein said reflective area comprises a reflective cup.

37. The LED package of claim 29, wherein said contrasting area is black.

38. The LED package of claim 29, wherein said contrasting area is around said reflective area.

39. The LED package of claim 29, wherein said contrasting area is at a level above said LED chip.
